(19) United States
(12) Patent Application Publication
(10) Pub. No.: US 2026/0362767 A1
(43) Pub. Date: Nov. 12, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Hsiao-Hua Hung, Hsinchu City (TW); Ming-Yen Chuang, Hsinchu City (TW); Yun-Feng Kao, New Taipei City (TW); Kuo-Chang Chiang, Hsinchu City (TW); Tsung-Han Wu, New Taipei City (TW); Chih-Yu Chang, New Taipei City (TW)

(21) Appl. No.: 19/204,895

(22) Filed: May 12, 2025

(51) Int. Cl. H10D 62/17; H10B 12/00; H10D 30/01; H10D 30/63; H10D 62/10; H10D 62/13

(52) U.S. Cl. CPC H10D 62/292; H10B 12/31; H10D 30/025; H10D 30/63; H10D 62/115; H10D 62/151

(57) ABSTRACT

The present disclosure, in some embodiments, relates to an integrated chip. The integrated chip includes a lower source/drain over a substrate, a channel arranged over the lower source/drain, and an upper source/drain over the channel. Gate structures are arranged along opposing sides of the channel. The channel includes a channel material laterally surrounding an insulating core. The channel material and the insulating core both extend to within an anchor region of the channel that is embedded within the lower source/drain.

### BACKGROUND

Modern-day integrated chips comprise millions or billions of semiconductor devices formed on a semiconductor substrate (e.g., a silicon substrate). The semiconductor devices are electrically coupled together by interconnects. The interconnects comprise interconnect wires and interconnect vias disposed within a dielectric structure over a semiconductor substrate. By using interconnects to electrically couple the semiconductor devices together, the semiconductor devices are able to perform logical functions that enable operation of an integrated chip.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates some embodiments of an integrated chip structure having a vertical transistor with a channel comprising an anchor region configured to contact an underlying source/drain.

FIG. 2 illustrates some additional embodiments of an integrated chip structure having a vertical transistor with a channel comprising an anchor region configured to contact an underlying source/drain.

FIG. 3 illustrates some additional embodiments of an integrated chip structure having a vertical transistor with a channel comprising an anchor region configured to contact an underlying source/drain.

FIG. 4 illustrates some additional embodiments of an integrated chip structure having a vertical transistor with a channel comprising an anchor region configured to contact an underlying source/drain.

FIGS. 5A-5B illustrate some additional embodiments of integrated chip structures having a vertical transistor with a channel comprising an anchor region configured to contact an underlying source/drain.

FIG. 6 illustrates some additional embodiments of an integrated chip structure having a vertical transistor with a channel comprising an anchor region configured to contact an underlying source/drain.

FIGS. 7A-7B illustrate some additional embodiments of an integrated chip memory structure having a vertical transistor with a channel comprising an anchor region configured to contact an underlying source/drain.

FIGS. 8-17 illustrate cross-sectional views of some embodiments of a method of forming an integrated chip structure having a vertical transistor with a channel comprising an anchor region configured to contact an underlying source/drain.

FIGS. 18-27 illustrate cross-sectional views of some additional embodiments of a method of forming an integrated chip structure having a vertical transistor with a channel comprising an anchor region configured to contact an underlying source/drain.

FIG. 28 illustrates a flow diagram of some embodiments of a method of forming an integrated chip structure having a vertical transistor with a channel comprising an anchor region configured to contact an underlying source/drain.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Vertical transistors (e.g., vertical field effect transistors (VFETs)) are transistors that have a channel structure extending between source and drain regions along a direction that is perpendicular to an upper surface of an underlying semiconductor substrate. Vertical transistors often have a source region and a drain region stacked onto one another, so as to allow current to flow vertically. Vertical transistors allow for the scale of transistors to shrink, thereby improving a density of integrated chip devices and a performance of integrated chips. The advantages realized by vertical transistors have applications in power electronics (e.g., with handling higher currents and voltages efficiently), high-frequency applications (e.g., due to fast switching capabilities), and the like.

Good electrical contact between a channel structure and source/drain contacts is important to enhance current delivery by reducing resistance and thus mitigating power loss and improving carrier mobility. However, during fabrication overlay errors (e.g., overlay shift) may cause a channel structure to be laterally offset from an underlying source/drain contact resulting in poor electrical contact between the channel structure and the underlying source/drain contact. It has been appreciated that in vertical transistors even a slight overlay shift during processing can lead to changes in performance. For example, an overlay shift may lead to increased contact resistance, which can affect the overall performance of a device, especially in applications that require low resistance to support high currents. Furthermore, the increased resistance may increase electrical power consumption, RC delay, and thermal breakdown, while poor electrical contact may lead to poor reliability (e.g., increase electromigration or other forms of degradation under high current densities) and unstable device performance in high-frequency applications (e.g., affecting a device's switching speed and efficiency).

The present disclosure relates to an integrated chip structure comprising a vertical transistor having a channel that includes an anchor region configured to contact an underlying source/drain. In some embodiments, the integrated chip structure comprises a lower source/drain over a substrate, a channel arranged over the lower source/drain, and an upper source/drain over the channel. Gate structures are arranged along opposing sides of the channel. The channel includes a channel material laterally surrounding an insulating core. The channel material and the insulating core both extend within an anchor region of the channel that is embedded within the lower source/drain. By having the anchor region of the channel extend into the lower source/drain, the anchor region is able to provide for good electrical contact between the lower source/drain and the channel in spite of overlay errors that may occur during processing.

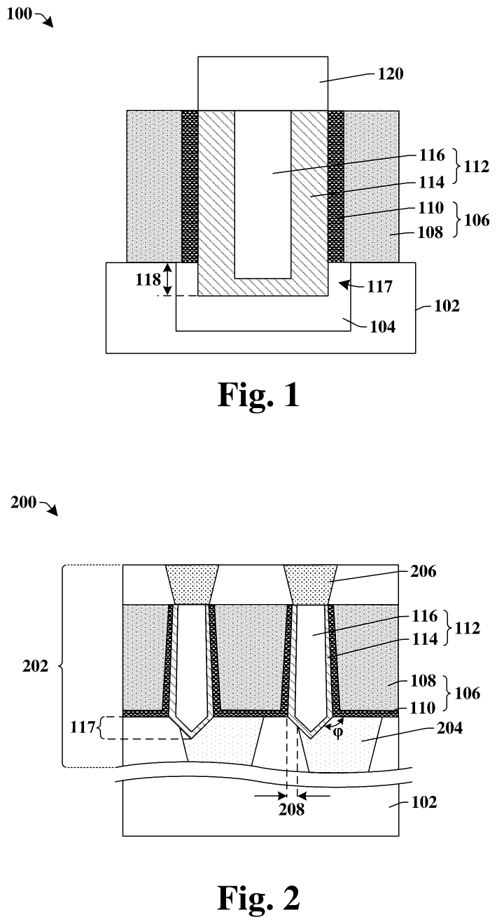

FIG. 1 illustrates some embodiments of an integrated chip structure 100 having a vertical transistor with a channel comprising an anchor region configured to contact an underlying source/drain.

The integrated chip structure 100 comprises a vertical transistor having a lower source/drain 104 vertically separated from an upper source/drain 120 by a channel 112. In some embodiments, the lower source/drain 104 may be disposed on, over, and/or within a substrate 102. One or more gate structures 106 are arranged along one or more sides of the channel 112 and above the lower source/drain 104. The one or more gate structures 106 respectively include a gate electrode 108 and a gate dielectric 110. The gate dielectric 110 separates the gate electrode 108 from the channel 112.

The channel 112 comprises a channel material 114 and an insulating core 116. The insulating core 116 is laterally surrounded on opposing sides by the channel material 114, so that the channel material 114 separates opposing sides of the insulating core 116 from the one or more gate structures 106. The insulating core 116 of the channel 112 improves insulating properties of the channel 112 and therefore reduces leakage currents between the lower source/drain 104 and the upper source/drain 120. The reduced leakage currents can reduce an overall power consumption (e.g., improve an overall energy efficiency) of an integrated chip structure 100.

The channel 112 further comprises an anchor region 117 that protrudes to a non-zero distance 118 below a bottommost surface of the gate structures 106 and to within the lower source/drain 104. In some embodiments, the anchor region 117 may comprise a part of the channel 112 that is below a topmost surface of the lower source/drain 104 and that is embedded between sidewalls of the lower source/drain 104. The anchor region 117 physically contacts the lower source/drain 104 along multiple different surfaces and/or directions (e.g., along a lateral direction and a vertical direction). In some embodiments, the anchor region 117 comprises both the channel material 114 and the insulating core 116. In such embodiments, both the channel material 114 and the insulating core 116 extend to non-zero distances below the bottommost surface of the gate structures 106.

By physically contacting the lower source/drain 104 along multiple different directions, the anchor region 117 of the channel 112 provides for good electrical and a reduced contact resistance between the channel 112 and the lower source/drain 104 in spite of overlay shift. Reducing the contact resistance may lead to more efficient device operation and stable performance in high-frequency applications due to reliable contact and reduced parasitic effects. It can also increase a thermal stability and a contact integrity, thereby improving a long-term reliability of the device by minimizing risks such as electromigration.

FIG. 2 illustrates some additional embodiments of an integrated chip structure 200 having a vertical transistor with a channel comprising an anchor region configured to contact an underlying source/drain.

The integrated chip structure 200 comprises an inter-level dielectric (ILD) structure 202 disposed over a substrate 102. The ILD structure 202 includes a plurality of ILD layers stacked onto one another. Vertical transistors are arranged within the ILD structure 202. The vertical transistors include lower source/drains separated from upper source/drains by a plurality of channels 112.

In some embodiments, the lower source/drains comprise a plurality of lower source/drain contacts 204 disposed within the ILD structure 202 and the upper source/drains comprise a plurality of upper source/drain contacts 206 disposed within the ILD structure 202 above the lower source/drain contacts 204. In some embodiments (not shown), one or more conductive interconnects (e.g., conductive contacts, interconnect wires, and/or interconnect vias) may be disposed within the ILD structure 202 between the plurality of lower source/drain contacts 204 and the substrate 102. In some embodiments, the plurality of lower source/drain contacts 204 may comprise source contacts and the plurality of upper source/drain contacts 206 may comprise drain contacts. In other embodiments, the plurality of lower source/drain contacts 204 may comprise drain contacts and the plurality of upper source/drain contacts 206 may comprise source contacts.

A plurality of gate structures 106 are arranged within the ILD structure 202 vertically between the plurality of lower source/drain contacts 204 and the plurality of upper source/drain contacts 206. The plurality of gate structures 106 are arranged along opposing sides of the plurality of lower source/drain contacts 204. For example, in some embodiments the plurality of gate structures 106 may straddle opposing outermost sidewalls of the plurality of lower source/drain contacts 204. The plurality of gate structures 106 include a gate electrode 108 and a gate dielectric 110 extending along outer surfaces of the gate electrode 108. In some embodiments, the gate dielectric 110 wraps around sidewalls and a bottommost surface of the gate electrode 108. In some embodiments, the gate dielectric 110 vertically separates the plurality of lower source/drain contacts 204 from the gate electrode 108. In some embodiments, the plurality of gate structures 106 may respectively have a width that increases as a height over the substrate 102 increases.

The plurality of channels 112 are arranged vertically between the plurality of lower source/drain contacts 204 and the plurality of upper source/drain contacts 206 and laterally between neighboring ones of the plurality of gate structures 106. In some embodiments, the gate dielectric 110 laterally separates the gate electrode 108 from the plurality of channels 112 disposed along opposing sides of the gate electrode 108. The plurality of channels 112 respectively comprise a channel material 114 and an insulating core 116. The insulating core 116 is laterally surrounded on opposing sides by the channel material 114, so that the channel material 114 laterally separates the insulating core 116 from the plurality of gate structures 106.

The plurality of channels 112 respectively comprise an anchor region 117 that extends to within the lower source/drain contacts 204. The anchor region 117 has multiple surfaces that physically contact the channel 112. In some embodiments, the anchor region 117 may comprise the channel material 114 and the insulating core 116. In such embodiments, the channel material 114 both vertically and laterally separates the insulating core 116 from the lower source/drain contacts 204. In some embodiments, the anchor region 117 may have angled sidewalls that give the anchor region a tapered profile. For example, the anchor region may have sidewalls that are angled to meet at a point that is within the plurality of lower source/drain contacts 204. In some embodiments, the sidewalls may be oriented at an angle φ measured with respect to the bottom of the gate dielectric 110. In some embodiments, the angle φ may be approximately 135°, between approximately 115° and approximately 150°, or other similar values. The tapered sidewalls give the anchor region 117 a width that increases as a height over the substrate 102 increases. In some embodiments, the plurality of channels 112 respectively have a maximum width at a top of the anchor region 117.

In some embodiments, there may be an overlay error 208 (e.g., an overlay shift) between the lower source/drain contacts 204 and the plurality of channels 112. The overlay error 208 may cause the lower source/drain contacts 204 to be laterally off centered from a respective overlying one of the plurality of channels 112. In some additional embodiments, the overlay error 208 may cause the lower source/drain contacts 204 to cover a part, but not all of the anchor region 117. Because the anchor region 117 vertically extends to within the lower source/drain contacts 204, the anchor region 17 allows for good electrical contact to be achieved between the lower source/drain contacts 204 and the plurality of channels 112 in spite of the overlay error 208.

FIG. 3 illustrates some additional embodiments of an integrated chip structure 300 having a vertical transistor with a channel comprising an anchor region configured to contact an underlying source/drain.

The integrated chip structure 300 comprises an ILD structure 202 disposed over a substrate 102. The ILD structure 202 includes a plurality of ILD layers 202a-202b stacked onto one another. For example, the ILD structure 202 may comprise a first ILD layer 202a and a second ILD layer 202b stacked onto the first ILD layer 202a. The plurality of ILD layers 202a-202b may respectively comprise silicon dioxide, silicon oxynitride (SiN), silicon carbon nitride (SiCN), titanium oxide (TiOx), amorphous silicon (a-Si), amorphous carbon (a-C), carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like. In some embodiments, the first ILD layer 202a may have a thickness that is in a range of between approximately 1 nanometer (nm) and approximately 150 nm, between approximately 50 nm and approximately 200 nm, between approximately 50 nm and approximately 150 nm, or other similar values.

A plurality of lower source/drain contacts 204 are disposed within the ILD structure 202. The plurality of lower source/drain contacts 204 may comprise a lower conductive fill 204C surrounded by a lower source/drain liner 204L. The lower conductive fill 204C comprises one or more surfaces (e.g., sidewalls) that form a channel recess. In some embodiments, the channel recess may have a triangular shape. In some embodiments, the lower source/drain liner 204L may comprise one or more of molybdenum (Mo), titanium (Ti), tantalum nitride (TaN), titanium nitride (TiN), tungsten (W), aluminum (Al), chromium (Cr), nickel (Ni), tantalum (Ta), ruthenium (Ru), cobalt (Co), copper (Cu), and/or the like. In some embodiments, the lower conductive fill 204C may comprise one or more of molybdenum (Mo), titanium (Ti), tungsten (W), tantalum nitride (TaN), titanium nitride (TiN), nickel (Ni), tantalum (Ta), ruthenium (Ru), a conductive oxide (e.g., indium oxide (InO), indium tin oxide (InSnO), etc.), and/or the like. In some embodiments, the lower conductive fill 204C and the lower source/drain liner 204L may respectively have a thickness that is in a range of between approximately 1 nm and approximately 50 nm, between approximately 10 nm and approximately 50 nm, or other similar values.

In some embodiments, the lower conductive fill 204C has one or more protrusions 306 formed by a sidewall of the lower conductive fill 204C that extends along a side of a plurality of gate structures 106 and directly between the plurality of gate structures 106 and a plurality of channels 112. In some embodiments, the sidewall extends outward from an upper surface of the lower conductive fill 204C. In some additional embodiments, the lower source/drain liner 204L may also comprise one or more protrusions 308 formed by a sidewall of the lower source/drain liner 204L that extends along a side of the plurality of gate structures 106 and directly between the plurality of gate structures 106 and the plurality of channels 112. In some embodiments, the sidewall extends outward from an upper surface of the lower source/drain liner 204L.

The plurality of gate structures 106 are arranged within the ILD structure 202 above and along opposing sides of the plurality of lower source/drain contacts 204. The plurality of gate structures 106 include a gate electrode 108 and a gate dielectric 110 extending along outer surfaces of the gate electrode 108. In some embodiments, the gate dielectric 110 may extend along sidewalls and a lower surface of the gate electrode 108. In some embodiments, the gate electrode 108 may comprise one or more of molybdenum (Mo), titanium (Ti), tungsten (W), tantalum nitride (TaN), titanium nitride (TiN), nickel (Ni), tantalum (Ta), ruthenium (Ru), and/or the like. In some embodiments, the gate electrode 108 may have a thickness that is in a range of between approximately 1 nm and approximately 50 nm, between approximately 20 nm and approximately 50 nm, or other similar values. In some embodiments, the gate dielectric 110 may comprise a high-k dielectric material (e.g., a material having a dielectric constant that is greater than approximately 3.9). In some embodiments, the gate dielectric 110 may comprise one or more of aluminum oxynitride (AlON), aluminum nitride (AlN), aluminum oxide (AlO), Hafnium oxide (HfO₂), Hafnium zirconium oxide (HZO), zirconium oxide (ZrO₂), indium zirconium oxide (InZrO), titanium oxide (TiOx), titanium aluminum oxide (TiAlO), tantalum oxide (Ta2O5), Hafnium titanium oxide (HfTiO), Hafnium lanthanum oxide (HfLaO), and/or the like. In some embodiments, the gate dielectric 110 may have a thickness that is in a range of between approximately 1 nm and approximately 15 nm, between approximately 5 nm and approximately 10 nm, or other similar values.

The plurality of channels 112 are arranged vertically above the plurality of lower source/drain contacts 204 and laterally between neighboring ones of the plurality of gate structures 106. The plurality of channels 112 respectively comprise a channel material 114 and an insulating core including a channel insulating material 304. The channel material 114 laterally surrounds the channel insulating material 304, so as to separate the channel insulating material 304 from the plurality of gate structures 106. In some embodiments, the channel material 114 may comprise one or more of indium gallium zinc (InₓGa_{y}Zn_{z}O) (0≤x, y, z≤1), InₓGa_{y}Zn_{z}MO (wherein M can be Ti, Al, Ag, W, Ce, Sn, and/or the like), indium gallium oxide (IGO), indium zinc oxide (IZO), indium tungsten oxide (IWO), one or more tin doped oxide semiconductor materials, and/or the like. In some embodiments, the channel insulating material 304 may comprise one or more of an oxide semiconductor, aluminum oxide (AlOx), silicon dioxide (SiO2), silicon oxynitride (SiON), silicon carbide (SiC), silicon nitride (SiN), silicon carbon nitride (SiCN), gallium oxide (GaO), hafnium oxide (HfO₂), tantalum oxide (Ta₂O₅), titanium oxide (TiOₓ), zirconium oxide (ZrO₂), and/or other non-conductive materials.

The plurality of channels 112 respectively comprise an anchor region 117 that extends into the channel recess of the lower source/drain contacts 204. The anchor region 117 includes both the channel material 114 and the channel insulating material 304. Both the channel material 114 and the channel insulating material 304 extend to non-zero distance below the gate structures 106. In some embodiments, the anchor region 117 may be laterally separated from the gate dielectric 110 by the lower conductive fill 204C. The lower conductive fill 204C may have a thickness that varies at different locations between the anchor region 117 and the lower source/drain liner 204L. For example, the lower conductive fill 204C may have a tapered width along opposing sides of the anchor region 117. The tapered widths cause a width of the lower conductive fill 204C along the opposing sides of the anchor region 117 to increase as a distance from the substrate 102 decreases.

In some embodiments, the anchor region 117 may have a triangular shape formed by tapered sidewalls that meet at a point that is vertically below a bottommost surface of the gate structures 106 and within the lower source/drain contacts 204. The anchor region 117 comprises a triangular section of the channel insulating material 304 and a section of the channel material 114 arranged along adjacent sides of the triangular section of the channel insulating material 304. In some embodiments, the tapered sidewalls of the anchor region 117 are completely covered by the lower conductive fill 204C.

In some embodiments, the plurality of channels 112 may have a height that is in a range of between approximately 10 nm and approximately 100 nm, between approximately 30 nm and approximately 80 nm, and/or other similar values. In some embodiments, the channel material 114 may have a smaller height than the gate dielectric 110. In some embodiments, the channel material 114 may have a thickness that is in a range of between approximately 1 nm and approximately 10 nm, between approximately 5 nm and approximately 10 nm, or other similar values. In some embodiments, the thickness of the channel material 114 may vary over a height of the channel material 114. For example, the thickness of the channel material 114 may decrease as a height of the channel material 114 increases. In some embodiments, the channel insulating material 304 may have a thickness that is in a range of between approximately 5 nm and approximately 20 nm, between approximately 5 nm and approximately 25 nm, or other similar values. In some embodiments, the thickness of the channel insulating material 304 may also vary over a height of the channel insulating material 304. For example, the thickness of the channel insulating material 304 may decrease as a height of the channel insulating material 304 increases.

A plurality of upper source/drain contacts 206 are disposed within the ILD structure 202 above the plurality of channels 112 and the plurality of gate structures 106. In some embodiments, the plurality of upper source/drain contacts 206 may comprise an upper source/drain liner 206L and an upper conductive fill 206C disposed over the upper source/drain liner 206L. In some embodiments, the upper source/drain liner 206L may comprise one or more of Mo, Ti, W, TaN, TiN, Ni, Ta, Ru, a conductive oxide (e.g., InO, InSnO, etc.), and/or the like. In some embodiments, the upper conductive fill 206C may comprise one or more of Mo, Ti, TaN, TiN, W, Al, Cr, Ni, Ta, Ru, Co, Cu, and/or the like. In some embodiments, the upper source/drain liner 206L and the upper conductive fill 206C may respectively have a thickness that is in a range of between approximately 1 nm and approximately 50 nm, between approximately 10 nm and approximately 50 nm, or other similar values.

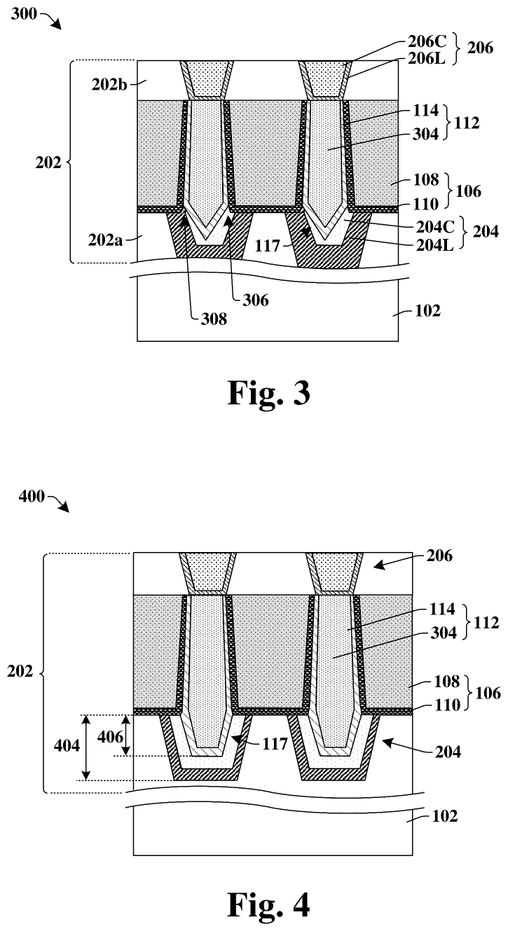

FIG. 4 illustrates some additional embodiments of an integrated chip structure 400 having a vertical transistor with a channel comprising an anchor region configured to contact an underlying source/drain.

The integrated chip structure 400 comprises a plurality of lower source/drain contacts 204 disposed within an ILD structure 202 over a substrate 102. In some embodiments, the plurality of lower source/drain contacts 204 may comprise a lower source/drain liner 204L and a lower conductive fill 204C disposed over the lower source/drain liner 204L. The plurality of lower source/drain contacts 204 comprise one or more surfaces (e.g., sidewalls) that form a channel recess. In some embodiments, the channel recess may have a trapezoidal shape formed by sidewalls and a horizontally extending surface of the lower source/drain contacts 204. A plurality of gate structures 106 are arranged within the ILD structure 202 above the plurality of lower source/drain contacts 204 and the first ILD layer 202a. The plurality of gate structures 106 are arranged along opposing sides of the plurality of lower source/drain contacts 204. The plurality of gate structures 106 include a gate electrode 108 and a gate dielectric 110 extending along outer surfaces of the gate electrode 108.

A plurality of channels 112 are arranged vertically above the plurality of lower source/drain contacts 204 and laterally between neighboring ones of the plurality of gate structures 106. A plurality of upper source/drain contacts 206 are disposed within the ILD structure 202 above the plurality of channels 112 and the plurality of gate structures 106. The plurality of channels 112 comprise a channel material 114 arranged along sidewalls of the plurality of gate structures 106 and a channel insulating material 304 arranged between interior sidewalls of the channel material 114.

The plurality of channels 112 further comprise an anchor region 117 that extends into the channel recess. The anchor region 117 may have a trapezoidal shape formed by tapered sidewalls that vertically extend to a horizontally extending lower surface of the channel 112, which is vertically below a bottom of the plurality of gate structures 106 and within the plurality of lower source/drain contacts 204. The anchor region 117 gives the plurality of channels 112 an irregular hexagonal shape. The anchor region 117 comprises a trapezoidal section of the channel insulating material 304 and a section of the channel material 114 arranged along adjacent sides of the trapezoidal section of the channel insulating material 304. In some embodiments, the tapered sidewalls of the anchor region 117 are completely covered by the lower conductive fill 204C.

In some embodiments, the lower source/drain contacts 204 may have a first height 404 that is in a range of between approximately 1 nm and approximately 100 nm, between approximately 30 nm and approximately 80 nm, and/or other similar values. In some embodiments, the anchor region 117 may have a second height 406 that is in a range of between approximately 1 nm and approximately 50 nm, between approximately 5 nm and approximately 20 nm, or other similar values. In some embodiments, a ratio of the second height 406 of the anchor region 117 to the first height 404 of the lower source/drain contacts 204 is in a range of between approximately 0.001 and approximately 0.9, between approximately 0.1 and approximately 0.5, or other similar values.

A plurality of upper source/drain contacts 206 are disposed within the ILD structure 202 above the plurality of channels 112 and the plurality of gate structures 106. In some embodiments, the plurality of upper source/drain contacts 206 may comprise an upper source/drain liner 206L and an upper conductive fill 206C disposed over the upper source/drain liner 206L.

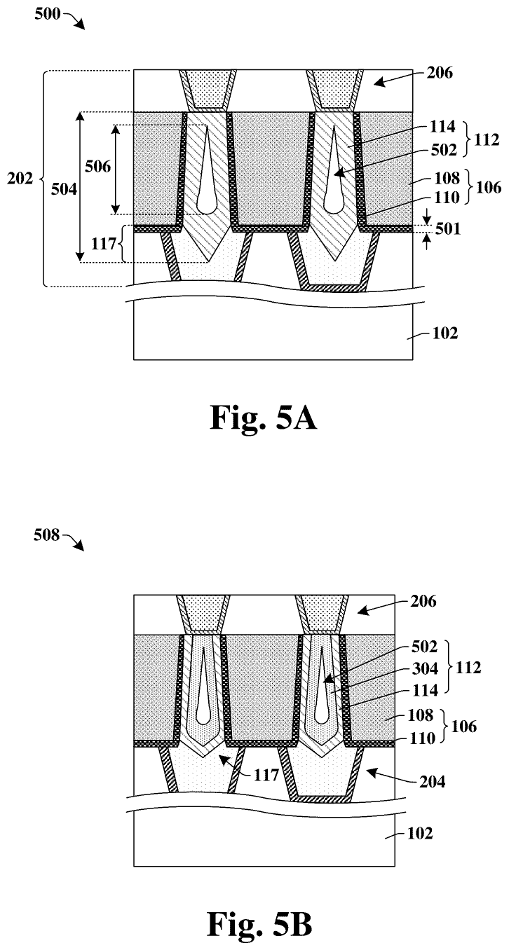

FIG. 5A illustrates some additional embodiments of an integrated chip structure 500 having a vertical transistor with a channel comprising an anchor region configured to contact an underlying source/drain.

The integrated chip structure 500 comprises a plurality of lower source/drain contacts 204 disposed within the ILD structure 202 over a substrate 102. The plurality of lower source/drain contacts 204 comprise one or more surfaces (e.g., sidewalls) that form a channel recess. A plurality of gate structures 106 are arranged within the ILD structure 202 above the plurality of lower source/drain contacts 204. The plurality of gate structures 106 are arranged along opposing sides of the plurality of lower source/drain contacts 204. The plurality of gate structures 106 include a gate electrode 108 and a gate dielectric 110. A plurality of channels 112 are arranged vertically above the plurality of lower source/drain contacts 204 and laterally between neighboring ones of the plurality of gate structures 106. A plurality of upper source/drain contacts 206 are disposed within the ILD structure 202 above the plurality of channels 112 and the plurality of gate structures 106.

The plurality of channels 112 comprise a channel material 114 arranged along sidewalls of the plurality of gate structures 106 and within the channel recess in the plurality of lower source/drain contacts 204. In some embodiments, plurality of lower source/drain contacts 204 may comprise a lower conductive fill 204C surrounded by a lower source/drain liner 204L. The lower conductive fill 204C may comprise a protrusion that extends outward from within the lower source/drain liner 204L to a non-zero distance 501 above a top of the lower source/drain liner 204L.

The channel material 114 has one or more internal surfaces that form an air-gap 502 within the plurality of channels 112. For example, the channel material 114 may comprise interior sidewalls that are spaced apart from one another by a space that forms the air-gap 502 directly over the lower source/drain contact 204. The air-gap 502 is laterally separated from the plurality of gate structures 106 by the channel material 114. In some embodiments, the air-gap 502 is over the anchor region 117 of the channel 112. In other embodiments, the air-gap 502 may extend into the anchor region 117 of the channel 112. In some embodiments, the channel material 114 continuously extends between neighboring ones of the plurality of gate structures 106 at a first height over the substrate 102 and is discontinuous between the neighboring ones of the plurality of gate structures 106 at a second height over the substrate 102 that is less than the first height. In some embodiments, the air-gap 502 may comprise one or more gases including one or more of oxygen, hydrogen, fluorinated gases (e.g., perfluorocarbons), hydrocarbon gases, and/or the like.

In some embodiments, the channel material 114 may have a first maximum height 504 and the air-gap 502 may have a second maximum height 506. In some embodiments, a ratio of the second maximum height 506 to the first maximum height 504 may be between approximately 0.001 and approximately 0.9, between approximately 0.1 and approximately 0.9, between approximately 0.5 and approximately 0.9, or other similar values.

FIG. 5B illustrates some additional embodiments of an integrated chip structure 508 having a vertical transistor with a channel comprising an anchor region configured to contact an underlying source/drain.

The integrated chip structure 508 comprises a channel 112 that includes a channel material 114 surrounding an insulating core comprising a channel insulating material 304 and an air-gap 502. The channel insulating material 304 is arranged along one or more interior surfaces (e.g., interior sidewalls) of the channel material 114. In some embodiments, the channel insulating material 304 completely covers the interior sidewalls of the channel material 114. The channel insulating material 304 has one or more internal surfaces that form an air-gap 502 within the plurality of channels 112. The air-gap 502 is laterally separated by the channel material 114 and the channel insulating material 304 from a plurality of gate structures 106.

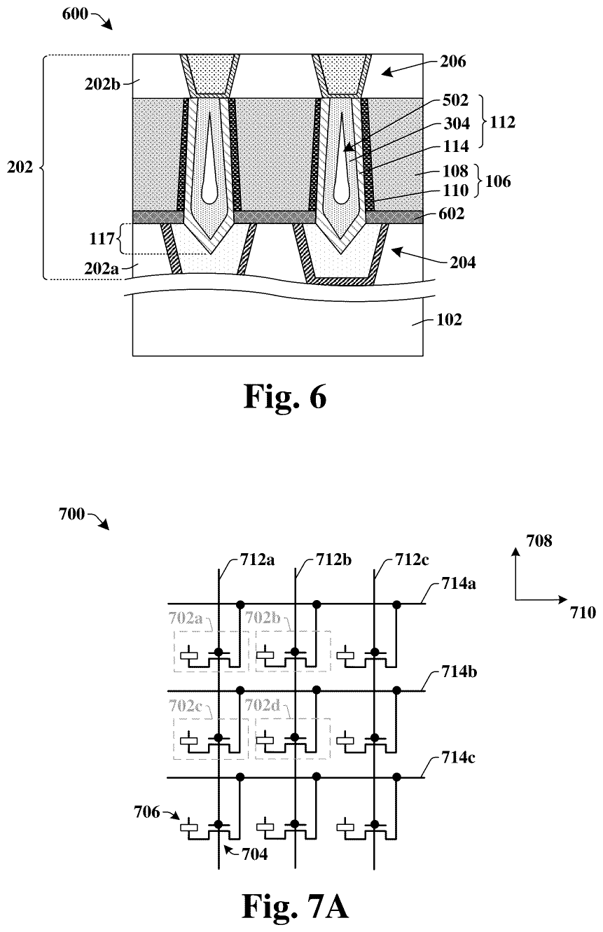

FIG. 6 illustrates some additional embodiments of an integrated chip structure 600 having a vertical transistor with a channel comprising an anchor region configured to contact an underlying source/drain.

The integrated chip structure 600 comprises an ILD structure 202 disposed over a substrate 102. The ILD structure 202 includes a plurality of ILD layers 202a-202b stacked onto one another. For example, the ILD structure 202 may comprise a first ILD layer 202a and a second ILD layer 202b stacked onto the first ILD layer 202a. A plurality of lower source/drain contacts 204 are disposed within the first ILD layer 202a. A dielectric layer 602 is arranged over the first ILD layer 202a and the plurality of lower source/drain contacts 204. In various embodiments, the dielectric layer 602 may comprise an oxide (e.g., silicon dioxide), a nitride (e.g., silicon nitride, silicon oxynitride, etc.), a carbide (e.g., silicon carbide, silicon oxycarbide, etc.), and/or the like. In some embodiments, the dielectric layer 602 may extend over parts of the plurality of lower source/drain contacts 204.

A plurality of gate structures 106 are arranged above the dielectric layer 602. In some embodiments, the dielectric layer 602 vertically separates the plurality of gate structures 106 from the plurality of lower source/drain contacts 204. The plurality of gate structures 106 include a gate electrode 108 and a gate dielectric 110. A plurality of channels 112 are arranged vertically above the plurality of lower source/drain contacts 204 and laterally between neighboring ones of the plurality of gate structures 106. The plurality of channels 112 vertically extend through the dielectric layer 602 to the plurality of lower source/drain contacts 204. A plurality of upper source/drain contacts 206 are disposed within the ILD structure 202 above the plurality of channels 112 and the plurality of gate structures 106.

The plurality of channels 112 comprise a channel material 114 arranged along sidewalls of the plurality of gate structures 106 and the dielectric layer 602. The channel material 114 surrounds an insulating core comprising a channel insulating material 304 and an air-gap 502. The insulating material 302 has one or more internal surfaces that form the air-gap 502. The air-gap 502 is laterally separated by the channel material 114 and the channel insulating material 304 from the plurality of gate structures 106.

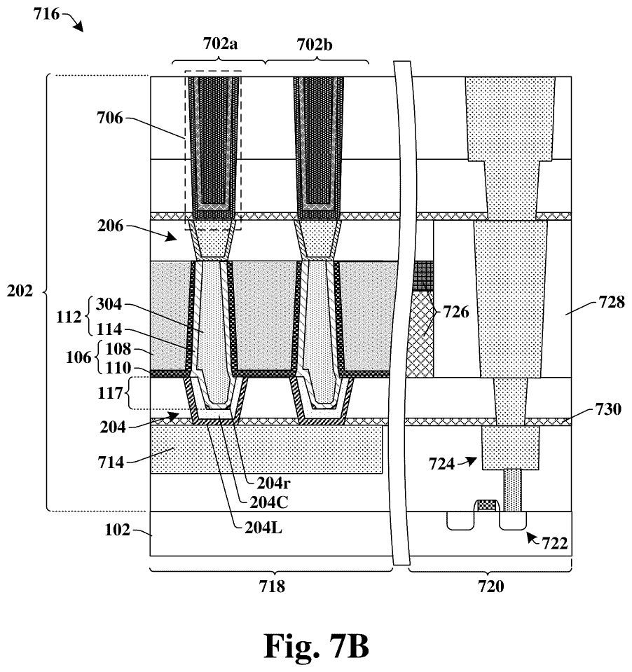

FIGS. 7A-7C illustrate some embodiments of an integrated chip memory structure having a vertical transistor with a channel comprising an anchor region configured to contact an underlying source/drain.

FIG. 7A illustrates a schematic diagram 700 of some embodiments of the disclosed integrated chip memory structure.

As shown in the schematic diagram 700, the integrated chip structure comprises a memory array including a plurality of memory cells 702a-702d arranged within columns (extending along a first direction 708) and rows (extending along a second direction 710). The plurality of memory cells 702a-702d respectively comprise an access transistor 704 and a data storage element 706. The access transistor 704 is configured to control access to the data storage element 706. The access transistor 704 comprises a gate electrode coupled to a plurality of word-lines 712a-712c. The access transistor 704 further comprises a source/drain region coupled to a plurality of bit-lines 714a-714c.

The plurality of word-lines 712a-712c and the plurality of bit-lines 714a-714c may be further coupled to control circuitry (e.g., a sense amplifier, decoder, etc.) configured to selectively control access to the plurality of memory cells 702a-702d. For example, in some embodiments a write operation may be performed on a first memory cell 702a by applying a positive write voltage to a first word-line 712a and a first bit-line 714a. In some embodiments, a read operation may be performed on the first memory cell by applying a read voltage (e.g., having a voltage that is less than the positive write voltage) to the first word-line 712a.

FIG. 7B illustrates a cross-sectional view 716 showing some embodiments of a disclosed integrated chip memory structure corresponding to a section of the schematic diagram 700 of FIG. 7A.

As shown in cross-sectional view 716, the integrated chip memory structure comprises an embedded memory region 718 and a logic region 720. The embedded memory region 718 includes a plurality of memory cells 702a-702b. The integrated chip memory structure comprises an ILD structure 202 disposed over a substrate 102. In some embodiments, the ILD structure 202 comprises a plurality of ILD layers stacked onto one another. In some embodiments, adjacent ones of the ILD layers may be separated from one another by etch stop layers 730.

The embedded memory region 718 comprises a plurality of gate structures 106 arranged within the ILD structure 202 between a plurality of lower source/drain contacts 204 and a plurality of upper source/drain contacts 206. The plurality of lower source/drain contacts 204 may be disposed on a bit-line 714. The plurality of gate structures 106 include a gate electrode 108 and a gate dielectric 110. A plurality of channels 112 are arranged vertically above the plurality of lower source/drain contacts 204 and laterally between neighboring ones of the plurality of gate structures 106. The plurality of channels 112 comprise a channel material 114 arranged along sidewalls of the plurality of gate structures 106.

The channel 112 comprises an anchor region 117 that is below a bottommost surface of the plurality of gate structures 106. In some embodiments, the anchor region 117 of the channel 112 may be substantially centered upon the lower source/drain contacts 204 and laterally off centered from an upper portion of the channel 112 that is between the plurality of gate structures 106. In some embodiments, the plurality of lower source/drain contacts 204 may comprise a lower source/drain liner 204L and a lower conductive fill 204C. In some embodiments, a sacrificial remnant may be disposed between the lower conductive fill 204C and the anchor region 117. The sacrificial remnant 204r may comprise a metal, such as Mo, Ti, W, TiN, TaN, Ta, Ru, Ni, and or the like.

The plurality of upper source/drain contacts 206 are coupled to a data storage element 706 configured to store a first data state (e.g., a logical ‘0’) or a second a second data state (e.g., a logical ‘1’). In some embodiments, the data storage element 706 may comprise a capacitor. In other embodiments, the data storage element 706 may comprise a resistive random access memory device (RRAM), a ferroelectric random access memory (FeRAM) device, a magneto resistive random access memory (MRAM) device, a phase change random access memory (PCRAM) device, and/or the like.

The logic region 720 comprises a logic device 722 (e.g., a field effect transistor (FET), a FinFET, a gate all around transistor, a nanosheet transistor, and/or the like). The logic device 722 is coupled to a plurality of overlying interconnects 724. In some embodiments, an edge of the memory array may comprise one or more sacrificial materials 726 laterally abutting an ILD layer 728 surrounding one or more of the interconnects 724. The one or more sacrificial materials 726 may comprise one or more of silicon dioxide (SiO₂), silicon oxynitride (SiON), silicon nitride (SiN), silicon carbon nitride (SiCN), titanium oxide (TiOx), amorphous silicon (a-Si), amorphous carbon (a-C), and/or other low-k dielectrics

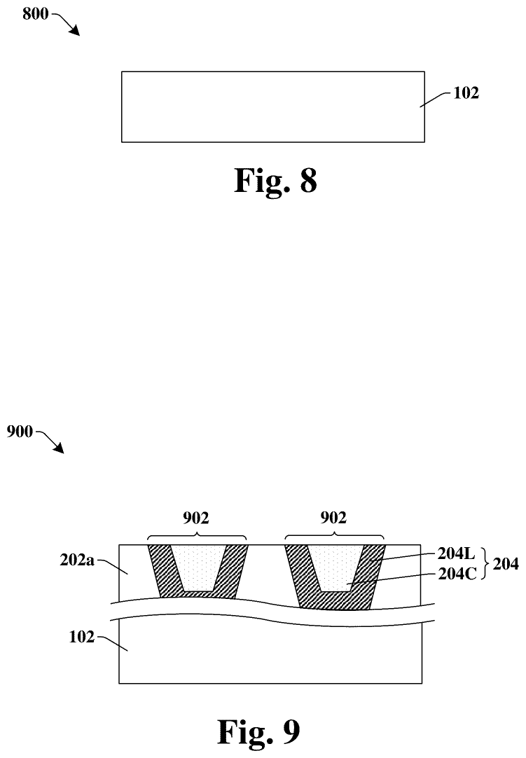

FIGS. 8-17 illustrate cross-sectional views 800-1700 of some embodiments of a method of forming an integrated chip structure having a vertical transistor with a channel comprising an anchor region configured to contact an underlying source/drain. Although the embodiments shown in FIGS. 8-17 are described with reference to a method, it will be appreciated that the structures shown in FIGS. 8-17 are not limited to the method of formation but rather may stand alone separate of the method.

As shown in cross-sectional view 800 of FIG. 8, a substrate 102 is provided. In various embodiments, the substrate 102 may comprise and/or be any type of semiconductor body (e.g., silicon/CMOS bulk, SiGe, SOI, etc.) such as a semiconductor wafer or one or more die on a wafer, as well as any other type of semiconductor and/or epitaxial layers formed thereon and/or otherwise associated therewith.

As shown in cross-sectional view 900 of FIG. 9, a first inter-level dielectric (ILD) layer 202a is formed over the substrate 102. In some embodiments, the first ILD layer 202a may be formed by one or more deposition processes (e.g., a physical vapor deposition (PVD) process, a chemical vapor deposition (CVD) process, a plasma enhanced CVD (PE-CVD) process, an atomic layer deposition (ALD) process, a plasma enhanced ALD (PE-ALD) process, a thermal ALD process, a spin-on process, a metal doping process, a metal oxidation process, a sputtering process, and/or the like). In some embodiments, the first ILD layer 202a may comprise silicon dioxide, silicon oxynitride (SiN), silicon carbon nitride (SiCN), titanium oxide (TiOx), amorphous silicon (a-Si), amorphous carbon (a-C), carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like. In some embodiments (not shown), one or more additional ILD layers may be disposed between the first ILD layer 202a and the substrate 102.

A patterning process is performed on the first ILD layer 202a to form a plurality of lower source/drain openings 902 respectively formed by sidewalls of the first ILD layer 202a. In some embodiments, the patterning process may comprise a lithography process followed by an etching process that selectively exposes the first ILD layer 202a to an etchant. In various embodiments, the etchant may comprise a dry etchant having an etching chemistry comprising a fluorine species (e.g., CF₄, CHF₃, C₄F₈, etc.) or a wet etchant comprising hydrofluoric acid (HF), potassium hydroxide (KOH), or the like

A plurality of lower source/drain contacts 204 are formed within the plurality of lower source/drain openings 902. In some embodiments, the plurality of lower source/drain contacts 204 may be formed by forming a lower source/drain liner 204L within the plurality of lower source/drain openings 902 and over the first ILD layer 202a. In some embodiments, the lower source/drain liner 204L may comprise one or more of molybdenum (Mo), titanium (Ti), tantalum nitride (TaN), titanium nitride (TiN), tungsten (W), aluminum (Al), chromium (Cr), nickel (Ni), tantalum (Ta), ruthenium (Ru), cobalt (Co), copper (Cu), and/or the like. A lower conductive fill 204C is subsequently formed over the lower source/drain liner 204L. In some embodiments, the lower conductive fill 204C may comprise one or more of molybdenum (Mo), titanium (Ti), tungsten (W), tantalum nitride (TaN), titanium nitride (TiN), nickel (Ni), tantalum (Ta), ruthenium (Ru), a conductive oxide (e.g., InO, InSnO, etc.), and/or the like. In some embodiments, the lower source/drain liner 204L and the lower conductive fill 204C may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, an ALD process, and/or the like). After forming the lower source/drain liner 204L and the lower conductive fill 204C, a planarization process (e.g., a chemical mechanical planarization (CMP) process) may be performed to remove parts of the lower source/drain liner 204L and the lower conductive fill 204C that are over the first ILD layer 202a.

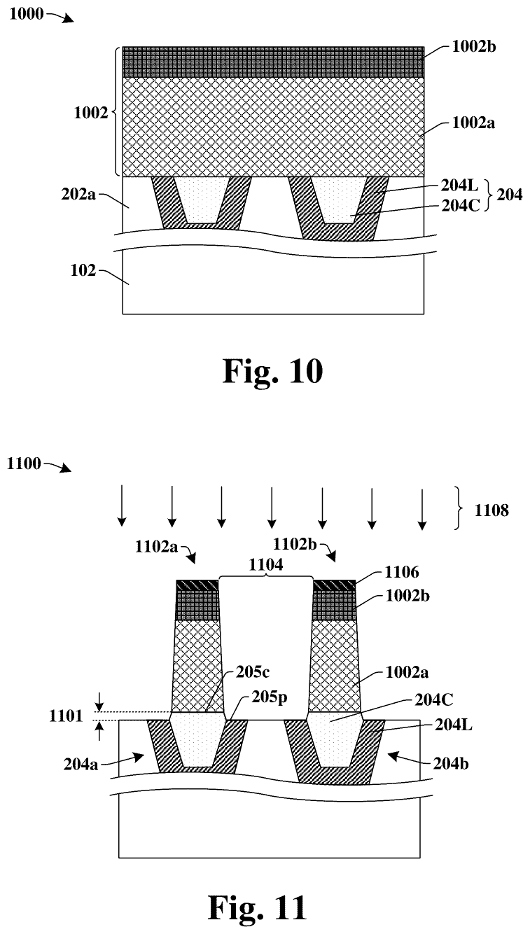

As shown in cross-sectional view 1000 of FIG. 10, a sacrificial structure 1002 is formed over the first ILD layer 202a and the lower source/drain contacts 204. In some embodiments, the sacrificial structure 1002 may comprise a first sacrificial material 1002a and a second sacrificial material 1002b stacked onto the first sacrificial material 1002a. In some embodiments, the first sacrificial material 1002a and the second sacrificial material 1002b may comprise one or more of silicon dioxide (SiO₂), silicon oxynitride (SiON), silicon nitride (SiN), silicon carbon nitride (SiCN), titanium oxide (TiOx), amorphous silicon (a-Si), amorphous carbon (a-C), and/or other low-k dielectrics. The sacrificial structure 1002 may be formed by one or more deposition processes (e.g., a PVD process, a CVD process, a PE-CVD process, a sputtering process, an ALD process, a PE-ALD process, a spin-on process, and/or the like). In some embodiments, the sacrificial structure 1002 may have a thickness that is in a range of between approximately 1 nm and approximately 150 nm, between approximately 50 nm and approximately 150 nm, or other similar values.

As shown in cross-sectional view 1100 of FIG. 11, the sacrificial structure (e.g., 1002 of FIG. 10) is selectively patterned to form a plurality of sacrificial pillars 1102a-1102b over the plurality of lower source/drain contacts 204a-204b. For example, a first sacrificial pillar 1102a is formed over a first lower source/drain contact 204a, a second sacrificial pillar 1102b is formed over a second lower source/drain contact 204b, etc. The plurality of sacrificial pillars 1102a-1102b are laterally separated from one another by gate structure openings 1104. In some embodiments, the plurality of sacrificial pillars 1102a-1102b respectively comprise the first sacrificial material 1002a and the second sacrificial material 1002b. In some embodiments, the parts of the lower source/drain contacts 204a-204b may also be removed, so that the lower source/drain contacts 204a-204b respectively comprise a central upper surface 205c and a peripheral upper surface 205p that is a non-zero distance 1101 vertically below and laterally surrounding the central upper surface 205c. The plurality of sacrificial pillars 1102a-1102b are disposed above the central upper surface 205c. In such embodiments, the lower conductive fill 204C may have an irregular hexagonal shape that protrudes outward to above the lower source/drain liner 204L.

In some embodiments, the sacrificial structure may be selectively patterned by patterning process that includes a lithography process that forms a mask 1106 over the sacrificial structure followed by an etching process that selectively exposes the sacrificial structure to an etchant 1108 according to the mask 1106. In various embodiments, the etchant 1108 may comprise a dry etchant having an etching chemistry comprising a fluorine species (e.g., CF₄, CHF₃, C₄F₈, etc.) or a wet etchant comprising hydrofluoric acid (HF), potassium hydroxide (KOH), or the like

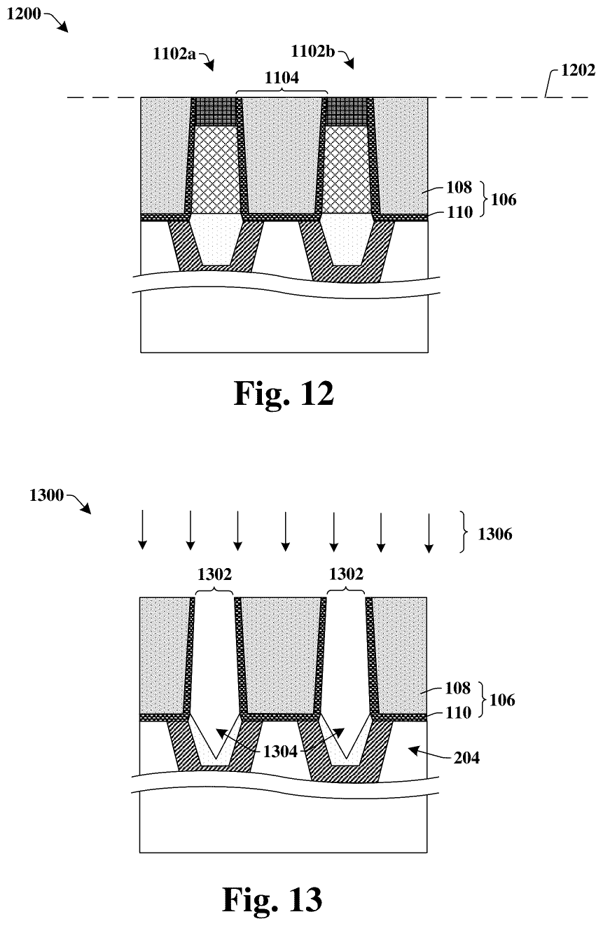

As shown in cross-sectional view 1200 of FIG. 12, a plurality of gate structures 106 are formed within the gate structure openings 1104 and on opposing sides of the plurality of sacrificial pillars 1102a-1102b. The plurality of gate structures 106 may be formed by depositing a gate dielectric 110 within the gate structure openings 1104 and over the plurality of sacrificial pillars 1102a-1102b. A gate electrode 108 may be subsequently deposited within the gate structure openings 1104 and over the gate dielectric 110. After forming the gate electrode 108, a planarization process 1202 (e.g., a CMP process) may be performed to remove parts of the gate dielectric 110 and the gate electrode 108 that are over the plurality of sacrificial pillars 1102a-1102b. The planarization process 1202 forms the plurality of gate structures 106.

In some embodiments, the gate dielectric 110 may comprise a high-k dielectric material. In some embodiments, the gate dielectric 110 may comprise one or more of aluminum oxynitride (AlON), aluminum nitride (AlN), aluminum oxide (AlO), Hafnium oxide (HfO₂), Hafnium zirconium oxide (HZO), zirconium oxide (ZrO₂), indium zirconium oxide (InZrO), titanium oxide (TiOx), titanium aluminum oxide (TiAlO), tantalum oxide (Ta2O5), Hafnium titanium oxide (HfTiO), Hafnium lanthanum oxide (HfLaO), and/or the like. In some embodiments, the gate electrode 108 may comprise one or more of molybdenum (Mo), titanium (Ti), tungsten (W), tantalum nitride (TaN), titanium nitride (TiN), nickel (Ni), tantalum (Ta), ruthenium (Ru), and/or the like. In some embodiments, the gate dielectric 110 and the gate electrode 108 may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, an ALD process, and/or the like).

As shown in cross-sectional view 1300 of FIG. 13, one or more etching processes 1306 are performed on the plurality of sacrificial pillars (e.g., 1102a-1102b of FIG. 12) and the lower source/drain contacts 204. The one or more etching processes 1306 remove the sacrificial pillars from between neighboring ones of the plurality of gate structures 106 to form a plurality of channel openings 1302 between the plurality of gate structures 106. The plurality of channel openings 1302 expose the lower source/drain contacts 204. The one or more etching processes 1306 further remove parts of the lower source/drain contacts 204 to form channel recesses 1304 within the lower source/drain contacts 204. In some embodiments, the one or more etching processes 1306 expose the plurality of sacrificial pillars and the lower source/drain contacts 204 to an etchant. In some embodiments, the channel recesses 1304 are formed by one or more interior surfaces of the lower source/drain contacts 204. For example, the channel recesses 1304 may be formed by sidewalls of the lower source/drain contacts 204 that meet at a point. In some embodiments, an etchant is brought into contact with the lower source/drain contacts 204 by way of the channel opening 1302 to form interior sidewalls of the lower source/drain contact 204 that form the channel recesses 1304.

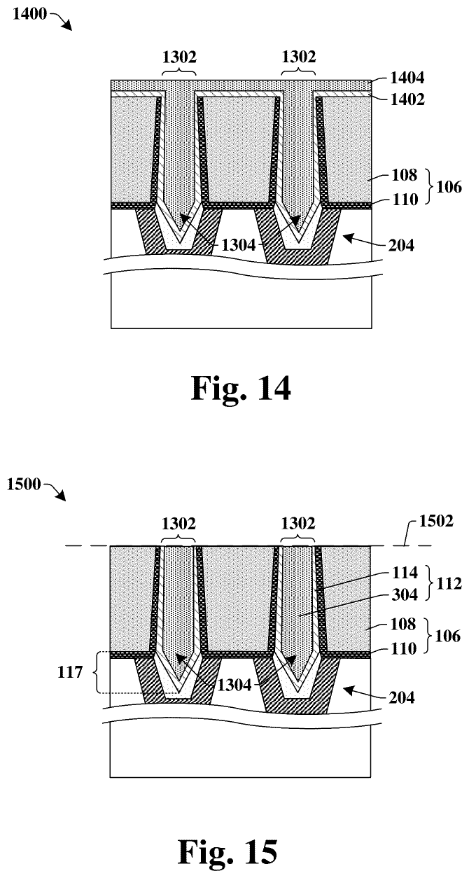

As shown in cross-sectional view 1400 of FIG. 14, a channel material layer 1402 is formed within the channel openings 1302 and the channel recesses 1304. The channel material layer 1402 lines the one or more interior surfaces of the lower source/drain contacts 204 and sidewalls and upper surfaces of the plurality of gate structures 106. The channel material layer 1402 comprises one or more interior surfaces that are spaced apart from one another by a space directly over the lower source/drain contacts 204. A channel insulating material layer 1404 is subsequently formed within the channel openings 1302 and lines sidewalls and upper surfaces of the channel material layer 1402. In some embodiments, the channel material layer 1402 may comprise one or more of indium gallium zinc (InₓGa_{y}Zn_{z}O) (0≤x, y, z≤1), InₓGa_{y}Zn_{z}MO (wherein M can be Ti, Al, Ag, W, Ce, Sn, and/or the like), indium gallium oxide (IGO), indium zinc oxide (IZO), indium tungsten oxide (IWO), tin doped oxide semiconductor materials, and/or the like. In some embodiments, the channel insulating material layer 1404 may comprise one or more of aluminum oxide (AlOx), silicon dioxide (SiO2), silicon oxynitride (SiON), silicon carbide (SiC), silicon nitride (SiN), silicon carbon nitride (SiCN), gallium oxide (GaO), hafnium oxide (HfO₂), tantalum oxide (Ta₂O₅), titanium oxide (TiOₓ), zirconium oxide (ZrO₂), and/or other non-conductive materials. In some embodiments, the channel material layer 1402 and/or the channel insulating material layer 1404 may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, and/or the like).

As shown in cross-sectional view 1500 of FIG. 15, a planarization process 1502 (e.g., a chemical mechanical planarization process) may be performed to remove parts of channel material layer (e.g., 1402 of FIG. 14) and the channel insulating material layer (e.g., 1404 of FIG. 14) that are over the plurality of gate structures 106. The planarization process 1502 forms a channel 112 comprising a channel material 114 and a channel insulating material 304. The channel 112 comprises an anchor region 117 that extends into the channel recess 1304. The anchor region 117 may have a triangular shape formed by tapered sidewalls that meet at a point that is vertically below a bottom of the gate structures 106 and within the lower source/drain contacts 204.

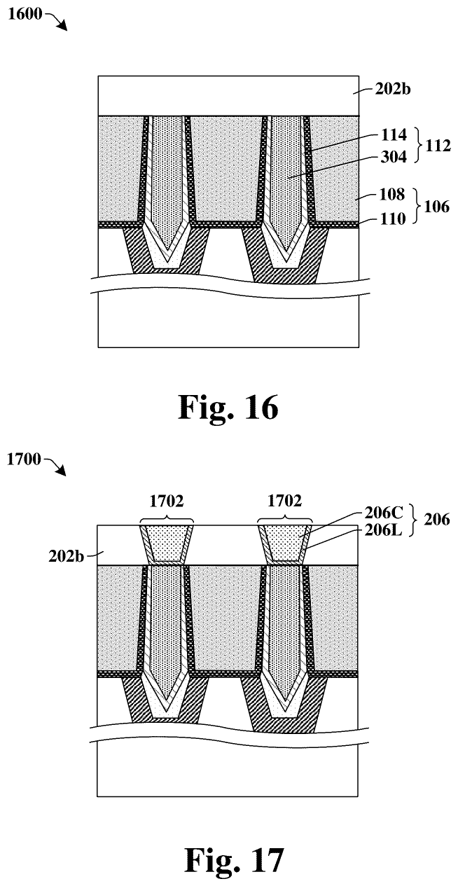

As shown in cross-sectional view 1600 of FIG. 16, a second ILD layer 202b is formed over the plurality of gate structures 106, the channel material 114, and the channel insulating material 304. In some embodiments, the second ILD layer 202b may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, and/or the like). In some embodiments, the second ILD layer 202b may comprise one or more of silicon dioxide, SiON, SiN, SiCN, TiOx, a-Si, a-C, SiCOH, PSG, BPSG, BSG, FSG, USG, and/or the like.

As shown in cross-sectional view 1700 of FIG. 17, a patterning process is performed on the second ILD layer 202b to form a plurality of upper source/drain openings 1702 respectively formed by sidewalls of the second ILD layer 202b. A plurality of upper source/drain contacts 206 are formed within the plurality of upper source/drain openings 1702. In some embodiments, the plurality of upper source/drain contacts 206 may be formed by forming an upper source/drain liner 206L within the plurality of upper source/drain openings 1702 and over the second ILD layer 202b. In some embodiments, the upper source/drain liner 206L may comprise one or more of Mo, Ti, W, TaN, TiN, Ni, Ta, Ru, a conductive oxide (e.g., InO, InSnO, etc.), and/or the like. An upper conductive fill 206C is subsequently formed over the upper source/drain liner 206L. In some embodiments, the upper conductive fill 206C may comprise one or more of Mo, Ti, TaN, TiN, W, Al, Cr, Ni, Ta, Ru, Co, Cu, and/or the like. In some embodiments, the upper source/drain liner 206L and the upper conductive fill 206C may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, and/or the like). After forming the upper source/drain liner 206L and the upper conductive fill 206C, a planarization process (e.g., a CMP process) may be performed to remove parts of the upper source/drain liner 206L and the upper conductive fill 206C that are over the second ILD layer 202b.

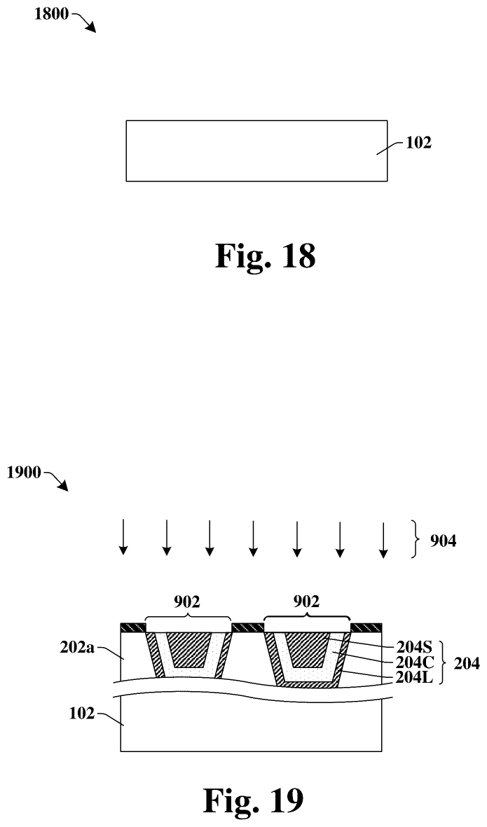

FIGS. 18-27 illustrate cross-sectional views of some additional embodiments of a method of forming an integrated chip structure having a vertical transistor with a channel comprising an anchor region configured to contact an underlying source/drain. Although the embodiments shown in FIGS. 18-27 are described with reference to a method, it will be appreciated that the structures shown in FIGS. 18-27 are not limited to the method of formation but rather may stand alone separate of the method.

As shown in cross-sectional view 1800 of FIG. 18, a substrate 102 is provided. In various embodiments, the substrate 102 may comprise and/or be any type of semiconductor body (e.g., silicon/CMOS bulk, SiGe, SOI, etc.) such as a semiconductor wafer or one or more die on a wafer, as well as any other type of semiconductor and/or epitaxial layers formed thereon and/or otherwise associated therewith.

As shown in cross-sectional view 1900 of FIG. 19, a first ILD layer 202a is formed over the substrate 102. A patterning process is performed on the first ILD layer 202a to form a plurality of lower source/drain openings 902 respectively formed by sidewalls of the first ILD layer 202a. In some embodiments, the patterning process may comprise a lithography process followed by an etching process that selectively exposes the first ILD layer 202a to an etchant 904.

A plurality of lower source/drain contacts 204 are formed within the plurality of lower source/drain openings 902. In some embodiments, the plurality of lower source/drain contacts 204 may be formed by forming a lower source/drain liner 204L within the plurality of lower source/drain openings 902 and over the first ILD layer 202a. A lower conductive fill 204C is subsequently formed over the lower source/drain liner 204L and a lower sacrificial material 204S is formed over the lower conductive fill 204C. After forming the lower source/drain liner 204L, the lower conductive fill 204C, and the lower sacrificial material 204S, a planarization process (e.g., a CMP process) may be performed to remove parts of the lower source/drain liner 204L, the lower conductive fill 204C, and the lower sacrificial material 204S that are over the first ILD layer 202a.

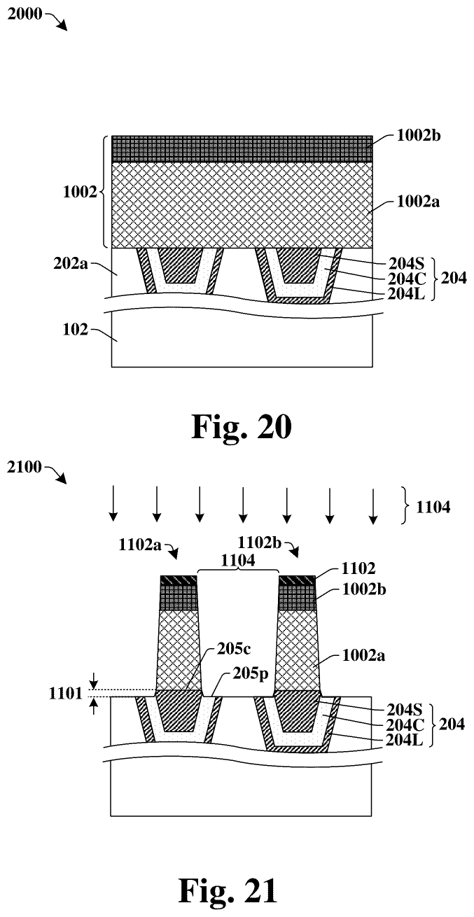

As shown in cross-sectional view 2000 of FIG. 20, a sacrificial structure 1002 is formed over the first ILD layer 202a and the lower source/drain contacts 204. In some embodiments, the sacrificial structure 1002 may comprise a first sacrificial material 1002a and a second sacrificial material 1002b stacked onto the first sacrificial material 1002a.

As shown in cross-sectional view 2100 of FIG. 21, the sacrificial structure (e.g., 1002 of FIG. 20) is selectively patterned to form a plurality of sacrificial pillars 1102a-1102b over the plurality of lower source/drain contacts 204. The plurality of sacrificial pillars 1102a-1102b are laterally separated from one another by gate structure openings 1104. In some embodiments, the plurality of sacrificial pillars 1102a-1102b respectively comprise the first sacrificial material 1002a and the second sacrificial material 1002b. In some embodiments, parts of the lower source/drain contacts 204 may also be removed, so that the lower source/drain contacts 204 respectively comprise a central upper surface 205c and a peripheral upper surface 205p that is vertically below and laterally surrounding the central upper surface 205c.

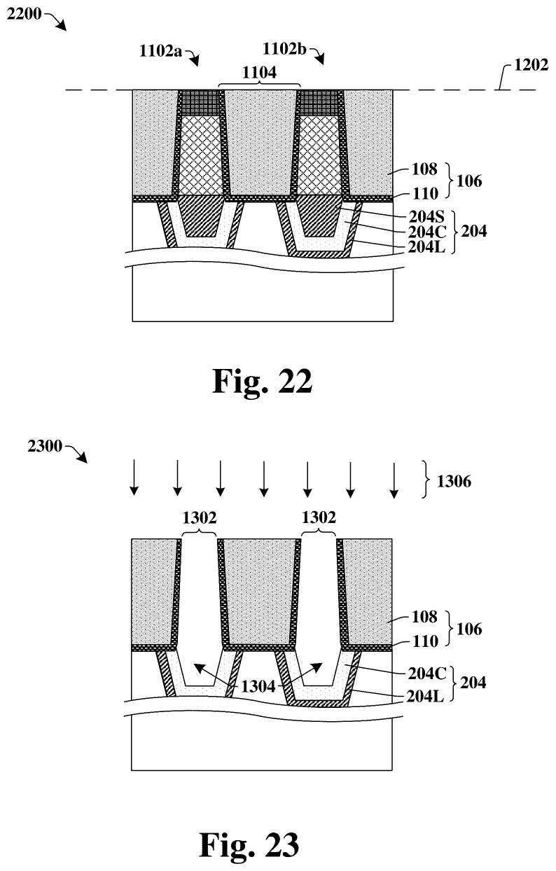

As shown in cross-sectional view 2200 of FIG. 22, a plurality of gate structures 106 are formed within the gate structure openings 1104 and on opposing sides of the plurality of sacrificial pillars 1102a-1102b. The plurality of gate structures 106 may be formed by depositing a gate dielectric 110 within the gate structure openings 1104 and over the plurality of sacrificial pillars 1102a-1102b. A gate electrode 108 may be subsequently deposited within the gate structure openings 1104 and over the gate dielectric 110. After forming the gate electrode 108, a planarization process 1202 (e.g., a CMP process) may be performed to remove parts of the gate dielectric 110 and the gate electrode 108 that are over the plurality of sacrificial pillars 1102a-1102b.

As shown in cross-sectional view 2300 of FIG. 23, one or more etching processes 1306 are performed on the plurality of sacrificial pillars (e.g., 1102a-1102b of FIG. 12) and the lower source/drain contacts 204. The one or more etching processes 1306 remove the sacrificial pillars from between neighboring ones of the plurality of gate structures 106 to form a plurality of channel openings 1302 between the plurality of gate structures 106. The plurality of channel openings 1302 expose the lower source/drain contacts 204. The one or more etching processes 1306 further remove the lower sacrificial material (e.g., 204S of FIG. 22) to form channel recesses 1304 within the lower source/drain contacts 204. The channel recesses 1304 are formed by one or more interior surfaces of the lower conductive fill 204C. For example, the channel recesses 1304 may be formed by sidewalls of the lower conductive fill 204C that are coupled to opposing sides of a horizontally extending surface of the lower conductive fill 204C.

In some embodiments, one or more etching processes 1306 may comprise an etchant that has a high etching selectivity between the lower conductive fill 204C and the lower sacrificial material. In some embodiments, one or more etching processes 1306 may completely remove the lower sacrificial material to form the channel recesses 1304. In other embodiments (not shown), the one or more etching processes 1306 may remove a part, but not all, of the lower sacrificial material to form the channel recesses 1304. In such embodiments, a sacrificial remnant may be left along one or more parts of the channel recesses 1304. In some embodiments (not shown), the lower source/drain contacts 204 may be subject to an overlay error with respect to the channel openings 1302. In such embodiments, the channel openings 1302 may be substantially centered upon the lower source/drain contacts 204 and laterally off centered from the channel recess 1304 (e.g., as shown in FIG. 7C).

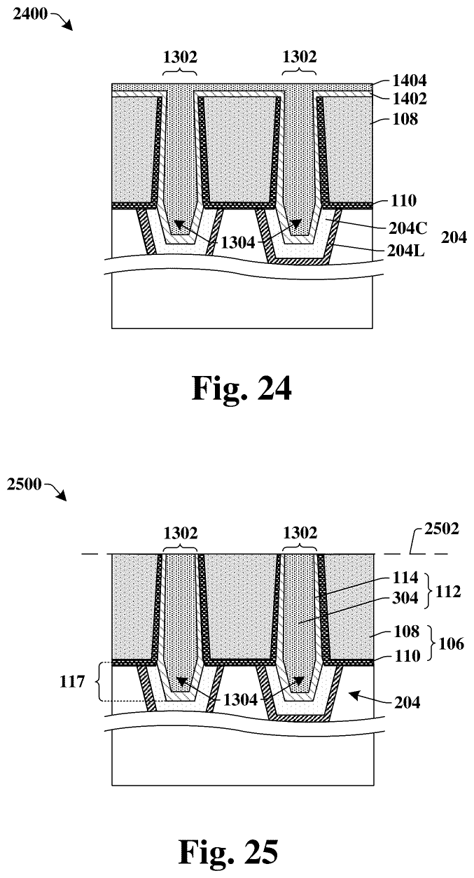

As shown in cross-sectional view 2400 of FIG. 24, a channel material layer 1402 is formed within the channel openings 1302, within the channel recess 1304, and along upper surfaces of the plurality of gate structures 106. A channel insulating material layer 1404 is subsequently formed within the channel openings 1302 and lining sidewalls and upper surfaces of the channel material layer 1402.

As shown in cross-sectional view 2500 of FIG. 25, a planarization process 2502 (e.g., a CMP process) may be performed to remove parts of channel material layer (e.g., 1402 of FIG. 24) and the channel insulating material layer (e.g., 1404 of FIG. 24) that are over the plurality of gate structures 106. The planarization process 2502 forms a channel 112 comprising a channel material 114 and a channel insulating material 304. The channel 112 comprises an anchor region 117 that extends into the channel recess 1304. The anchor region 117 may have a trapezoidal shape formed by tapered sidewalls that vertically extend to a horizontally extending lower surface that is vertically below a bottom of the gate structures 106 and within the lower source/drain contacts 204. The resulting channel 112 may have an irregular hexagonal shape.

As shown in cross-sectional view 2600 of FIG. 26, a second ILD layer 202b is formed over the plurality of gate structures 106 and the channel 112. In some embodiments, the second ILD layer 202b may be formed by one or more deposition processes (e.g., a PVD process, a CVD process, a PE-CVD process, an ALD process, a sputtering process, and/or the like). In some embodiments, the second ILD layer 202b may comprise silicon dioxide, SiON, SiN, SiCN, TiOx, a-Si, a-C, SiCOH, PSG, BPSG, BSG, FSG, USG, and/or the like.

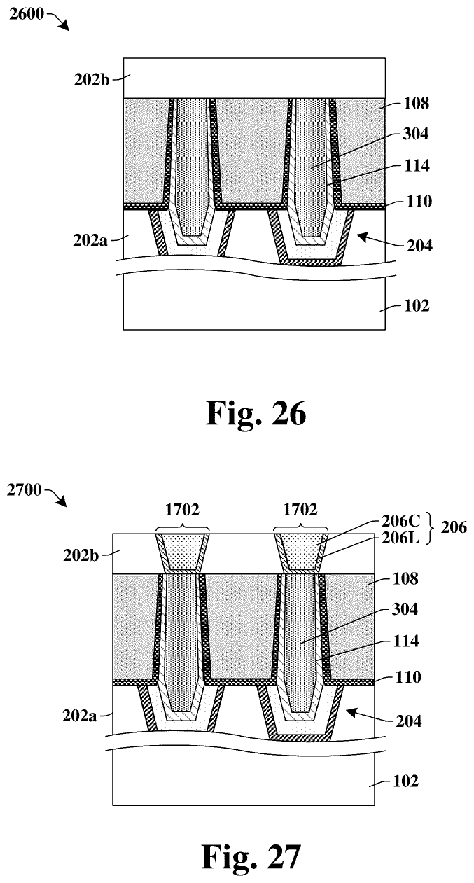

As shown in cross-sectional view 2700 of FIG. 27, a patterning process is performed on the second ILD layer 202b to form a plurality of upper source/drain openings 1702 respectively formed by sidewalls of the second ILD layer 202b. A plurality of upper source/drain contacts 206 are formed within the plurality of upper source/drain openings 1702. In some embodiments, the plurality of upper source/drain contacts 206 may be formed by forming an upper source/drain liner 206L within the plurality of upper source/drain openings 1702 and over the second ILD layer 202b. An upper conductive fill 206C is subsequently formed over the upper source/drain liner 206L. After forming the upper source/drain liner 206L and the upper conductive fill 206C, a planarization process (e.g., a CMP process) may be performed to remove parts of the upper source/drain liner 206L and the upper conductive fill 206C that are over the second ILD layer 202b.

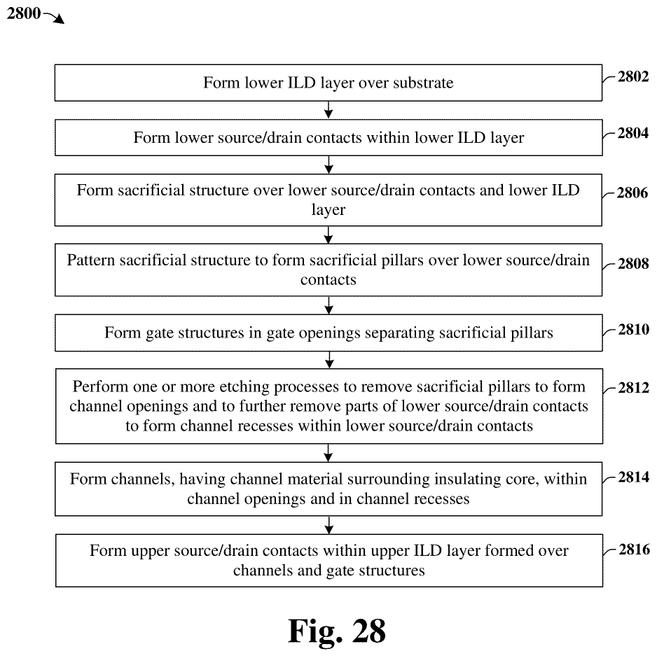

FIG. 28 illustrates a flow diagram of some embodiments of a method of forming an integrated chip structure having a vertical transistor with a channel comprising a channel material surrounding an insulating core.

While method 2800 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2802, a lower inter-level dielectric (ILD) layer is formed over a substrate. FIG. 8 illustrates a cross-sectional view 800 of some embodiments corresponding to act 2802. FIG. 18 illustrates a cross-sectional view 1800 of some additional embodiments corresponding to act 2802.

At act 2804, a plurality of lower source/drain contacts are formed within the lower ILD layer. FIG. 9 illustrates a cross-sectional view 900 of some embodiments corresponding to act 2804. FIG. 19 illustrates a cross-sectional view 1900 of some additional embodiments corresponding to act 2804.

At act 2806, a sacrificial structure is formed over the plurality of lower source/drain contacts and the lower ILD layer. FIG. 10 illustrates a cross-sectional view 1000 of some embodiments corresponding to act 2806. FIG. 20 illustrates a cross-sectional view 2000 of some additional embodiments corresponding to act 2806.

At act 2808, the sacrificial structure is patterned to form a plurality of sacrificial pillars over the plurality of lower source/drain contacts. FIG. 11 illustrates a cross-sectional view 1100 of some embodiments corresponding to act 2808. FIG. 21 illustrates a cross-sectional view 2100 of some additional embodiments corresponding to act 2808.

At act 2810, a plurality of gate structures are formed within gate openings separating the plurality of sacrificial pillars. FIG. 12 illustrates a cross-sectional view 1200 of some embodiments corresponding to act 2810. FIG. 22 illustrates a cross-sectional view 2200 of some additional embodiments corresponding to act 2810.

At act 2812, one or more etching processes are performed to remove the plurality of sacrificial pillars to form channel openings and to further remove parts of lower source/drain contacts to form channel recesses within the lower source/drain contacts. FIG. 13 illustrates a cross-sectional view 1300 of some embodiments corresponding to act 2812. FIG. 23 illustrates a cross-sectional view 2300 of some additional embodiments corresponding to act 2812.

At act 2814, channels are formed within the channel openings and in the channel recesses. The channels comprise a channel material surrounding an insulating core. FIGS. 14-15 illustrate cross-sectional views 1400-1500 of some embodiments corresponding to act 2814. FIGS. 24-25 illustrate cross-sectional views 2400-2500 of some additional embodiments corresponding to act 2814.

At act 2816, a plurality of upper source/drain contacts are formed within an upper ILD layer formed over the channels and the plurality of gate structures. FIGS. 16-17 illustrate cross-sectional views 1600-1700 of some embodiments corresponding to act 2816. FIGS. 26-27 illustrate cross-sectional views 2600-2700 of some additional embodiments corresponding to act 2816.

Accordingly, in some embodiments, the present disclosure relates to an integrated chip structure comprising a vertical transistor having a channel comprising an anchor region configured to contact an underlying source/drain.

In some embodiments, the present disclosure relates to an integrated chip. The integrated chip includes a lower source/drain over a substrate; a channel arranged over the lower source/drain; an upper source/drain over the channel; gate structures arranged along opposing sides of the channel; and the channel includes a channel material laterally surrounding an insulating core, the channel material and the insulating core both extending to within an anchor region of the channel that is embedded within the lower source/drain.

In other embodiments, the present disclosure relates to method of forming an integrated chip. The method includes forming a lower source/drain contact within a lower inter-level dielectric (ILD) layer over a substrate; forming a sacrificial structure over the lower source/drain contact and the lower ILD layer; patterning the sacrificial structure to form a sacrificial pillar over the lower source/drain contact; forming gate structures over the lower ILD layer and along opposing sidewalls of the sacrificial pillar; performing one or more etching processes to remove the sacrificial pillar to form a channel opening between the gate structures and to remove a part of the lower source/drain contact and form a channel recess extending into the lower source/drain contact; and forming a channel within the channel opening and the channel recess, the channel including a channel material surrounding a channel insulating material.

In yet other embodiments, the present disclosure relates to a method of forming an integrated chip. The method includes forming a lower source/drain contact within a lower inter-level dielectric (ILD) layer over a substrate; forming a sacrificial pillar over the lower source/drain contact; forming gate structures over the lower ILD layer and along opposing sidewalls of the sacrificial pillar; removing the sacrificial pillar to form a channel opening between the gate structures; and bringing an etchant into contact with the lower source/drain contact by way of the channel opening, the etchant forming interior sidewalls of the lower source/drain contact; and forming a channel material within the channel opening and along the interior sidewalls of the lower source/drain contact, wherein the channel material includes one or more interior surfaces that are spaced apart from one another by a space directly over the lower source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a lower source/drain over a substrate;
a channel arranged over the lower source/drain;
an upper source/drain over the channel;
gate structures arranged along opposing sides of the channel; and
wherein the channel comprises a channel material laterally surrounding an insulating core, the channel material and the insulating core both extending to within an anchor region of the channel that is embedded within the lower source/drain.

2. The integrated chip of claim 1, wherein the insulating core comprises a channel insulating material having a triangular shape, the channel material covering sidewalls of the channel insulating material.

3. The integrated chip of claim 1, wherein the insulating core comprises a channel insulating material having a trapezoidal shape, the channel material covering sidewalls and a horizontally extending lower surface of the channel insulating material.

4. The integrated chip of claim 1, wherein the lower source/drain comprises a lower source/drain liner and a lower conductive fill, the lower conductive fill laterally and vertically separating the channel from the lower source/drain liner.

5. The integrated chip of claim 1, wherein the channel material surrounds an air-gap disposed between the gate structures, the air-gap being over the anchor region.

6. The integrated chip of claim 5, wherein the lower source/drain has one or more protrusions formed by a sidewall of the lower source/drain, the sidewall of the lower source/drain extending outward from an upper surface of the lower source/drain to along a side of the gate structures.

7. The integrated chip of claim 5, wherein the anchor region of the channel is substantially centered upon the lower source/drain and laterally off centered from an upper portion of the channel that is between the gate structures.

8. The integrated chip of claim 1, wherein the lower source/drain comprises a lower source/drain liner and a lower conductive fill, the lower conductive fill having a tapered width along opposing sides of the anchor region.

9. The integrated chip of claim 1, wherein the lower source/drain is laterally off centered from the channel.

10. A method of forming an integrated chip, comprising:
forming a lower source/drain contact within a lower inter-level dielectric (ILD) layer over a substrate;
forming a sacrificial structure over the lower source/drain contact and the lower ILD layer;
patterning the sacrificial structure to form a sacrificial pillar over the lower source/drain contact;
forming gate structures over the lower ILD layer and along opposing sidewalls of the sacrificial pillar;
performing one or more etching processes to remove the sacrificial pillar to form a channel opening between the gate structures and to remove a part of the lower source/drain contact and form a channel recess extending into the lower source/drain contact; and
forming a channel within the channel opening and the channel recess, wherein the channel comprises a channel material surrounding a channel insulating material.

11. The method of claim 10, wherein the lower source/drain contact comprises a lower source/drain liner and a lower conductive fill disposed over the lower source/drain liner, the channel recess being formed by sidewalls of the lower conductive fill.

12. The method of claim 10, wherein forming the channel comprises:
depositing the channel material within the channel opening and the channel recess, wherein the channel material lines sidewalls of the gate structures and the lower source/drain contact; and
depositing the channel insulating material within the channel opening and the channel recess, wherein the channel insulating material lines sidewalls and an upper surface of the channel material.

13. The method of claim 10, wherein the lower source/drain contact comprises a lower source/drain liner, a lower conductive fill disposed over the lower source/drain liner, and a lower sacrificial material over the lower conductive fill, the one or more etching processes removing the lower sacrificial material to form the channel recess.

14. The method of claim 13, wherein the one or more etching processes completely remove the lower sacrificial material to form the channel recess.

15. The method of claim 10, wherein the channel material and the channel insulating material both extend to non-zero distances below a bottommost surface of the gate structures.

16. The method of claim 10, wherein the channel has an irregular hexagonal shape.

17. A method of forming an integrated chip, comprising:
forming a lower source/drain contact within a lower inter-level dielectric (ILD) layer over a substrate;
forming a sacrificial pillar over the lower source/drain contact;
forming gate structures over the lower ILD layer and along opposing sidewalls of the sacrificial pillar;
removing the sacrificial pillar to form a channel opening between the gate structures; and
bringing an etchant into contact with the lower source/drain contact by way of the channel opening, the etchant forming interior sidewalls of the lower source/drain contact; and
forming a channel material within the channel opening and along the interior sidewalls of the lower source/drain contact, wherein the channel material comprises one or more interior surfaces that are spaced apart from one another by a space directly over the lower source/drain contact.

18. The method of claim 17, wherein sidewalls of the channel material continuously extend to directly between the interior sidewalls of the lower source/drain contact.

19. The method of claim 17, wherein the channel material has opposing tapered sidewalls that meet at point below a top of the lower source/drain contact.

20. The method of claim 17, wherein the channel material has opposing sidewalls that are coupled to a horizontally extending surface.
